(19) United States
(12) Patent Application Publication
(10) Pub. No.: US 2018/0222038 A1
(43) Pub. Date: Aug. 9, 2018

(54) CONVEYING DEVICE

(71) Applicant: NITTO DENKO CORPORATION, Osaka (JP)

(72) Inventors: Youhei MAENO, Osaka (JP); Akira SUZUKI, Osaka (JP)

(21) Appl. No.: 15/750,340

(22) PCT Filed: Aug. 3, 2016
(86) PCT No.: PCT/JP2016/072740

§ 371 Date: Feb. 5, 2018

(30) Foreign Application Priority Data
Aug. 7, 2015 (JP) 2015-156710

(51) Int. Cl. B25J 5/02; B25J 15/00; B25J 17/02; B25J 9/06; H01L 21/677; H01L 21/687

(52) U.S. Cl. CPC B25J 5/02; B25J 15/00; H01L 21/68707; B25J 9/06; H01L 21/67706; B25J 17/025

(57) ABSTRACT

Provided is a transport apparatus which exhibits a strong gripping force, hardly contaminates an object being transported, and has excellent heat resistance. Also provided are a method of manufacturing a semiconductor device and a method of manufacturing an optical member in which the object is transported at high speed. The transport apparatus of the present invention includes a transport member comprising a carrying member and a mounting member; the mounting member includes a fibrous columnar structure; the fibrous columnar structure includes a fibrous columnar structure including a plurality of fibrous columnar objects; the plurality of fibrous columnar objects are each aligned in a direction substantially perpendicular to the carrying member; and a surface of the fibrous columnar structure on a side opposite to the carrying member has a coefficient of static friction against a glass surface of 2.0 or more.

### TECHNICAL FIELD

The present invention relates to a transport apparatus.

### BACKGROUND ART

In transporting a material, a production intermediate, a product, or the like (hereinafter sometimes referred to as “object to be processed”) in a manufacturing process for a semiconductor device or the like, the object to be processed is transported through use of a carrying member, such as a movable arm or a movable table (see, for example, Patent Literatures 1 and 2). In such transport, there is a demand for a member on which the object to be processed is to be mounted (mounting member) to have such a strong gripping force as to prevent the object to be processed from shifting in position while being transported. In addition, such demand has increased year by year along with a demand for a faster manufacturing process.

However, a related-art mounting member is formed of an elastic material, such as a resin, and has a problem in that the elastic material is liable to adhere and remain on the object to be processed. In addition, the mounting member formed of the elastic material, such as a resin, has low heat resistance, and has a problem in that its gripping force is reduced under a high temperature environment.

When a material such as ceramics is used for the mounting member, contamination of the object to be processed is prevented, and temperature dependence of a gripping force is reduced. However, a mounting member formed of such material has a problem of inherently having a weak gripping force, and being unable to sufficiently retain the object to be processed even at normal temperature.

### CITATION LIST

### Patent Literature

[PTL 1] JP 2001-351961 A

[PTL 2] JP 2013-138152 A

### SUMMARY OF INVENTION

### Technical Problem

An object of the present invention is to provide a transport apparatus which exhibits a strong gripping force, hardly contaminates an object to be processed (object to be transported), and is excellent in heat resistance. Other objects of the present invention are to provide a method of manufacturing a semiconductor device and a method of manufacturing an optical member in each of which an object to be processed can be transported at high speed.

### Solution to Problem

According to one aspect of the present invention, there is provided a transport apparatus, including a transport member, in which: the transport member includes a carrying member and a mounting member; the mounting member includes a fibrous columnar structure; the fibrous columnar structure includes a fibrous columnar structure including a plurality of fibrous columnar objects; the plurality of fibrous columnar objects are each aligned in a direction substantially perpendicular to the carrying member; and a surface of the fibrous columnar structure on a side opposite to the carrying member has a coefficient of static friction against a glass surface of 2.0 or more.

In one embodiment, the transport apparatus includes an arm part and a hand part connected to one end of the arm part, the arm part is arranged so as to be rotatable in a horizontal direction about another end of the arm part as a center of a rotation axis, and the hand part includes the transport member.

In one embodiment, the arm part has a multi-joint structure.

In one embodiment, the transport apparatus includes an arm part and a hand part connected to both ends of the arm part, the arm part is arranged so as to be rotatable in a horizontal direction substantially about a middle of the arm part as a center of a rotation axis, and the hand part includes the transport member.

In one embodiment, in the transport apparatus, the transport member is configured to travel on a traveling track.

In one embodiment, the transport apparatus includes the traveling track and a carriage arranged so as to travel on the traveling track, and the transport member is arranged on the carriage.

According to another aspect of the present invention, there is provided a transport method. The transport method includes transporting an object to be transported by retaining the object to be transported by the transport member, in which: the transport member includes a carrying member and a mounting member; the mounting member includes a fibrous columnar structure; the fibrous columnar structure includes a fibrous columnar structure including a plurality of fibrous columnar objects; the plurality of fibrous columnar objects are each aligned in a direction substantially perpendicular to the carrying member; and a surface of the fibrous columnar structure on a side opposite to the carrying member has a coefficient of static friction against a glass surface of 2.0 or more.

In one embodiment, the transport method includes using the transport apparatus.

According to another aspect of the present invention, there is provided a method of manufacturing a semiconductor device. The manufacturing method includes using the transport apparatus.

In one embodiment, the method of manufacturing a semiconductor device includes a plurality of steps, and the method includes transporting an object to be processed to be subjected to each of the plurality of steps constituting the method through use of the transport apparatus.

According to another aspect of the present invention, there is provided a method of manufacturing an optical member. The manufacturing method includes using the transport apparatus.

In one embodiment, the method of manufacturing an optical member includes a plurality of steps, and the method includes transporting an object to be processed to be subjected to each of the plurality of steps constituting the method through use of the transport apparatus.

### Advantageous Effects of Invention

According to the present invention, the transport apparatus which exhibits a strong gripping force, hardly contaminates an object to be processed (object to be transported), and is excellent in heat resistance can be provided. According to the present invention, the method of manufacturing a semiconductor device and the method of manufacturing an optical member in each of which an object to be processed can be transported at high speed can also be provided.

### BRIEF DESCRIPTION OF DRAWINGS

FIG. 1 is a schematic sectional view of an example of a semiconductor transport member according to one embodiment of the present invention.

FIG. 2 is a schematic sectional view of a production apparatus for a carbon nanotube aggregate according to one embodiment of the present invention.

FIG. 3 is a schematic view of a transport apparatus according to one embodiment of the present invention.

FIG. 4 is a schematic view of a transport apparatus according to one embodiment of the present invention.

FIG. 5 is a schematic view for illustrating a manufacturing process including using a transport apparatus according to one embodiment of the present invention.

### DESCRIPTION OF EMBODIMENTS

A transport apparatus of the present invention includes a transport member. The transport member includes a mounting member including a fibrous columnar structure.

The transport apparatus of the present invention may be suitably used in, for example, a manufacturing process for a semiconductor device or a manufacturing process for an optical member. More specifically, in the manufacturing process for a semiconductor device, the transport apparatus of the present invention may be used for transporting a material, a production intermediate, a product, or the like (specifically, a semiconductor material, a wafer, a chip, a film, or the like) from one step to another or in a predetermined step. Alternatively, in the manufacturing process for an optical member, the transport apparatus of the present invention may be used for transporting a glass substrate or the like from one step to another or in a predetermined step. A material, a production intermediate, a product, or the like which may be transported by the transport apparatus of the present invention is hereinafter sometimes referred to as “object to be processed” or “object to be transported.”

A. Transport Member

The transport member includes a carrying member and a mounting member.

Any appropriate carrying member may be adopted as the carrying member. Examples of such carrying member include a transport arm, a transport table, a transport ring, a transport guide rail, a storage cassette, a hook, and a transport frame. The size and shape of the carrying member may be appropriately selected depending on purposes. In addition, any appropriate material may be adopted as a material for forming the carrying member. In one embodiment, a ceramics material, such as alumina or silicon nitride; or a heat resistant material, such as stainless steel, is used as the material for forming the carrying member.

The mounting member is a member on which an object to be transported, which is to be transported by the transport apparatus of the present invention, is to be mounted. As described above, the mounting member includes a fibrous columnar structure. The mounting member including a fibrous columnar structure is excellent in heat resistance, non-contaminating property, and gripping property.

The mounting member may include any appropriate other member as long as the mounting member includes the fibrous columnar structure to the extent that the effect of the present invention is not impaired. In order to sufficiently express the effect of the present invention, the mounting member preferably consists of the fibrous columnar structure.

The fibrous columnar structure is a fibrous columnar structure including a plurality of fibrous columnar objects.

The length of each of the fibrous columnar objects is preferably from 50 μm to 3,000 μm, more preferably from 200 μm to 2,000 μm, still more preferably from 300 μm to 1, 500 μm, particularly preferably from 400 μm to 1,000 μm, most preferably from 500 μm to 1,000 μm. When the length of each of the fibrous columnar objects falls within the above-mentioned range, a mounting member which exhibits a strong gripping force and hardly contaminates the object to be transported can be formed.

The mounting member may be arranged on the entire surface of the carrying member or on part of the surface of the carrying member.

In one embodiment, the fibrous columnar objects each have a portion including at least an end thereof covered by an inorganic material. As used herein, the phrase “portion including at least an end” means a portion including at least an end of each of the fibrous columnar objects, that is, an end of each of the fibrous columnar objects on the opposite side to the side on which the carrying member is arranged.

All the fibrous columnar objects may each have a portion including at least an end thereof covered by the inorganic material, or part of the fibrous columnar objects may each have a portion including at least an end thereof covered by the inorganic material. The content of the fibrous columnar objects each having a portion including at least an end thereof covered by the inorganic material in the entirety of the fibrous columnar objects included in the mounting member is preferably from 50 wt % to 100 wt %, more preferably from 60 wt % to 100 wt %, still more preferably from 70 wt % to 100 wt %, even still more preferably from 80 wt % to 100 wt %, particularly preferably from 90 wt % to 100 wt %, most preferably substantially 100 wt %. When the content of the fibrous columnar objects each having a portion including at least an end thereof covered by the inorganic material in the entirety of the fibrous columnar objects included in the mounting member falls within the above-mentioned range, a mounting member which exhibits a strong gripping force and hardly contaminates the object to be transported can be formed.

When the portion including at least an end of each of the fibrous columnar objects is covered by the inorganic material, the portion covered has a covering layer having a thickness of preferably 1 nm or more, more preferably 3 nm or more, still more preferably 5 nm or more, even still more preferably 7 nm or more, particularly preferably 9 nm or more, most preferably 10 nm or more. The upper limit value of the thickness of the covering layer is preferably 50 nm, more preferably 40 nm, still more preferably 30 nm, particularly preferably 20 nm, most preferably 15 nm. When the thickness of the covering layer falls within the above-mentioned range, a mounting member which exhibits a strong gripping force and hardly contaminates the object to be transported can be formed.

When the portion including at least an end of each of the fibrous columnar objects is covered by the inorganic material, the portion covered has a covering layer having a length of preferably from 1 nm to 1,000 nm, more preferably from 5 nm to 700 nm, still more preferably from 10 nm to 500 nm, particularly preferably from 30 nm to 300 nm, most preferably from 50 nm to 100 nm. When the length of the covering layer falls within the above-mentioned range, a mounting member which exhibits a strong gripping force and hardly contaminates the object to be transported can be formed.

When the portion including at least an end of each of the fibrous columnar objects is covered by the inorganic material, any appropriate inorganic material may be adopted as the inorganic material to the extent that the effect of the present invention is not impaired. Examples of such inorganic material include SiO₂, Al₂O₃, Fe₂O₃, TiO₂, MgO, Cu, Ag, and Au.

The transport member may include a binder between the carrying member and the mounting member. Any appropriate binder may be adopted as such binder as long as the binder has such an effect that the carrying member and the mounting member can be bonded to each other. Examples of such binder include carbon paste, alumina paste, silver paste, nickel paste, gold paste, aluminum paste, titanium oxide paste, iron oxide paste, chromium paste, aluminum, nickel, chromium, copper, gold, and silver. When such binder is included, there can be provided a transport member in which the carrying member and the mounting member are sufficiently bonded to each other, and which includes a mounting member capable of expressing a stronger gripping force and more unlikely to cause a contaminant to adhere and remain on a side of the object to be transported.

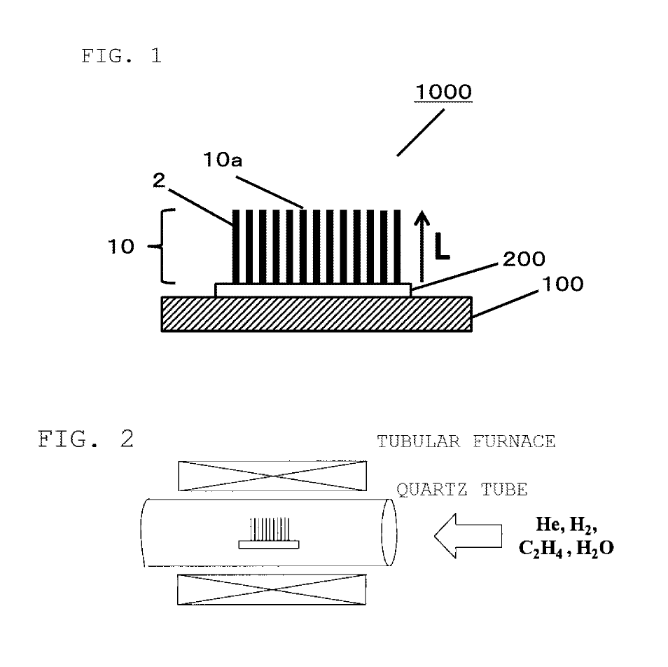

In FIG. 1, a schematic sectional view of an example of a transport member according to one embodiment of the present invention is illustrated.

In FIG. 1, a transport member 1000 includes a carrying member 100, a binder 200, and a fibrous columnar structure 10 serving as a mounting member.

In FIG. 1, the fibrous columnar structure 10 includes a plurality of fibrous columnar objects 2. One end of each of the fibrous columnar objects 2 is fixed onto the binder 200. The fibrous columnar objects 2 are each aligned in the direction of a length L. The fibrous columnar objects 2 are each aligned in a direction substantially perpendicular to the carrying member 100. The term “direction substantially perpendicular” as used herein means that the angle of the object with respect to the surface of the carrying member 100 is preferably 90°±20°, more preferably 90°±15°, still more preferably 90°±10°, particularly preferably 90°±5°.

A mode in which the mounting member (fibrous columnar structure) is arranged on one side of the carrying member is illustrated in FIG. 1, but the mounting member (fibrous columnar structure) may be arranged on both sides of the carrying member.

In the transport member, the surface of the fibrous columnar structure on the opposite side to the carrying member has a coefficient of static friction against a glass surface of 2.0 or more. In FIG. 1, the “surface of the fibrous columnar structure on the opposite side to the carrying member” refers to a surface 10a of the fibrous columnar structure 10 on the opposite side to the carrying member 100.

In the transport member, the surface of the fibrous columnar structure on the opposite side to the carrying member has a coefficient of static friction against a glass surface of 2.0 or more, preferably 2.4 or more, more preferably 3.0 or more, still more preferably 3.4 or more, even still more preferably 3.5 or more, particularly preferably 3.6 or more, most preferably 3.7 or more. In the transport member, the upper limit value of the coefficient of static friction against a glass surface of the surface of the fibrous columnar structure on the opposite side to the carrying member is preferably 10. When the coefficient of static friction against a glass surface of the surface of the fibrous columnar structure on the opposite side to the carrying member falls within the above-mentioned range in the transport member, there can be provided a transport member that includes a mounting member capable of expressing a strong gripping force and unlikely to cause a contaminant to adhere and remain on a side of the object to be transported. Needless to say, the transport member having a large coefficient of friction against a glass surface is capable of expressing a strong gripping force also for an object to be transported that is formed of a material other than glass (for example, a semiconductor wafer).

Any appropriate material may be adopted as a material for each of the fibrous columnar objects. Examples thereof include: metals, such as aluminum and iron; inorganic materials, such as silicon; and carbon materials, such as a carbon nanofiber and a carbon nanotube (CNT). Through use of those materials, a transport member more excellent in heat resistance can be obtained.

The diameter of each of the fibrous columnar objects is preferably from 0.3 nm to 2,000 nm, more preferably from 1 nm to 1,000 nm, still more preferably from 2 nm to 500 nm, particularly preferably from 2 nm to 200 nm, most preferably from 2 nm to 100 nm. When the diameter of each of the fibrous columnar objects falls within the above-mentioned range, a mounting member which exhibits a strong gripping force and hardly contaminates the object to be transported can be formed.

The fibrous columnar structure is preferably a carbon nanotube aggregate including a plurality of carbon nanotubes. In this case, the fibrous columnar objects are preferably carbon nanotubes.

When the fibrous columnar structure is the carbon nanotube aggregate, a mounting member which exhibits a strong gripping force, hardly contaminates the object to be transported, and has high heat resistance can be formed.

For the carbon nanotube aggregate, for example, the following embodiments (a first embodiment and a second embodiment) may be adopted.

A first embodiment of the carbon nanotube aggregate includes a plurality of carbon nanotubes, in which the carbon nanotubes each have a plurality of walls, the distribution width of the wall number distribution of the carbon nanotubes is 10 walls or more, and the relative frequency of the mode of the wall number distribution is 25% or less. When the carbon nanotube aggregate has such configuration, a mounting member which exhibits a strong gripping force and hardly contaminates the object to be transported can be formed.

In the first embodiment, the distribution width of the wall number distribution of the carbon nanotubes is preferably 10 walls or more, more preferably from 10 walls to 30 walls, still more preferably from 10 walls to 25 walls, particularly preferably from 10 walls to 20 walls. When the distribution width of the wall number distribution of the carbon nanotubes is adjusted to fall within the above-mentioned range, a mounting member which exhibits a strong gripping force and hardly contaminates the object to be transported can be formed.

The “distribution width” of the wall number distribution of the carbon nanotubes refers to a difference between the maximum wall number and minimum wall number of the wall numbers of the carbon nanotubes. When the distribution width of the wall number distribution of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

The wall number and the wall number distribution of the carbon nanotubes may be measured with any appropriate device. The wall number and wall number distribution of the carbon nanotubes are preferably measured with a scanning electron microscope (SEM) or a transmission electron microscope (TEM). For example, at least 10, preferably 20 or more carbon nanotubes may be taken out from the carbon nanotube aggregate to evaluate the wall number and the wall number distribution by the measurement with the SEM or the TEM.

In the first embodiment, the maximum wall number of the wall numbers of the carbon nanotubes is preferably from 5 to 30, more preferably from 10 to 30, still more preferably from 15 to 30, particularly preferably from 15 to 25. When the maximum wall number of the wall numbers of the carbon nanotubes is adjusted to fall within the above-mentioned range, a mounting member which exhibits a strong gripping force and hardly contaminates the object to be transported can be formed.

In the first embodiment, the minimum wall number of the wall numbers of the carbon nanotubes is preferably from 1 to 10, more preferably from 1 to 5. When the minimum wall number of the wall numbers of the carbon nanotubes is adjusted to fall within the above-mentioned range, a mounting member which exhibits a strong gripping force and hardly contaminates the object to be transported can be formed.

In the first embodiment, when the maximum wall number and minimum wall number of the wall numbers of the carbon nanotubes are adjusted to fall within the above-mentioned ranges, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the first embodiment, the relative frequency of the mode of the wall number distribution of the carbon nanotubes is preferably 25% or less, more preferably from 1% to 25%, still more preferably from 5% to 25%, particularly preferably from 10% to 25%, most preferably from 15% to 25%. When the relative frequency of the mode of the wall number distribution of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the first embodiment, the mode of the wall number distribution of the carbon nanotubes is present at preferably from 2 walls to 10 walls in number, more preferably from 3 walls to 10 walls in number. When the mode of the wall number distribution of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the first embodiment, regarding the shape of each of the carbon nanotubes, the lateral section of the carbon nanotube only needs to have any appropriate shape. The lateral section is of, for example, a substantially circular shape, an oval shape, or an n-gonal shape (n represents an integer of 3 or more).

In the first embodiment, the length of each of the carbon nanotubes is preferably 50 μm or more, more preferably from 100 μm to 3,000 μm, still more preferably from 300 μm to 1,500 μm, even still more preferably from 400 μm to 1,000 μm, particularly preferably from 500 μm to 1,000 μm. When the length of each of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the first embodiment, the diameter of each of the carbon nanotubes is preferably from 0.3 nm to 2,000 nm, more preferably from 1 nm to 1,000 nm, still more preferably from 2 nm to 500 nm. When the diameter of each of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the first embodiment, the specific surface area and density of each of the carbon nanotubes may be set to any appropriate values.

The second embodiment of the carbon nanotube aggregate includes a plurality of carbon nanotubes, in which the carbon nanotubes each have a plurality of walls, the mode of the wall number distribution of the carbon nanotubes is present at 10 or less walls in number, and the relative frequency of the mode is 30% or more. When the carbon nanotube aggregate has such configuration, a mounting member which exhibits a strong gripping force and hardly contaminates the object to be transported can be formed.

In the second embodiment, the distribution width of the wall number distribution of the carbon nanotubes is preferably 9 walls or less, more preferably from 1 wall to 9 walls, still more preferably from 2 walls to 8 walls, particularly preferably from 3 walls to 8 walls. When the distribution width of the wall number distribution of the carbon nanotubes is adjusted to fall within the above-mentioned range, a mounting member which exhibits a strong gripping force and hardly contaminates the object to be transported can be formed.

In the second embodiment, the maximum wall number of the wall numbers of the carbon nanotubes is preferably from 1 to 20, more preferably from 2 to 15, still more preferably from 3 to 10. When the maximum wall number of the wall numbers of the carbon nanotubes is adjusted to fall within the above-mentioned range, a mounting member which exhibits a strong gripping force and hardly contaminates the object to be transported can be formed.

In the second embodiment, the minimum wall number of the wall numbers of the carbon nanotubes is preferably from 1 to 10, more preferably from 1 to 5. When the minimum wall number of the wall numbers of the carbon nanotubes is adjusted to fall within the above-mentioned range, a mounting member which exhibits a strong gripping force and hardly contaminates the object to be transported can be formed.

In the second embodiment, when the maximum wall number and minimum wall number of the wall numbers of the carbon nanotubes are adjusted to fall within the above-mentioned ranges, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the second embodiment, the relative frequency of the mode of the wall number distribution of the carbon nanotubes is preferably 30% or more, more preferably from 30% to 100%, still more preferably from 30% to 90%, particularly preferably from 30% to 80%, most preferably from 30% to 70%. When the relative frequency of the mode of the wall number distribution of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the second embodiment, the mode of the wall number distribution of the carbon nanotubes is present at preferably 10 or less walls in number, more preferably from 1 wall to 10 walls in number, still more preferably from 2 walls to 8 walls in number, particularly preferably from 2 walls to 6 walls in number. When the mode of the wall number distribution of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the second embodiment, regarding the shape of each of the carbon nanotubes, the lateral section of the carbon nanotube only needs to have any appropriate shape. The lateral section is of, for example, a substantially circular shape, an oval shape, or an n-gonal shape (n represents an integer of 3 or more).

In the second embodiment, the length of each of the carbon nanotubes is preferably 50 μm or more, more preferably from 550 μm to 3,000 μm, still more preferably from 600 μm to 2,000 μm, even still more preferably from 650 μm to 1,000 μm, particularly preferably from 700 μm to 1,000 μm. When the length of each of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the second embodiment, the diameter of each of the carbon nanotubes is preferably from 0.3 nm to 2,000 nm, more preferably from 1 nm to 1,000 nm, still more preferably from 2 nm to 500 nm. When the diameter of each of the carbon nanotubes is adjusted to fall within the above-mentioned range, the carbon nanotubes can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

In the second embodiment, the specific surface area and density of each of the carbon nanotubes may be set to any appropriate values.

Any appropriate method may be adopted as a method of producing the carbon nanotube aggregate.

The method of producing the carbon nanotube aggregate is, for example, a method of producing a carbon nanotube aggregate aligned substantially perpendicularly from a smooth substrate by chemical vapor deposition (CVD) involving forming a catalyst layer on the substrate and filling a carbon source under a state in which a catalyst is activated with heat, plasma, or the like to grow the carbon nanotubes. In this case, for example, the removal of the substrate provides a carbon nanotube aggregate aligned in a lengthwise direction.

Any appropriate substrate may be adopted as the substrate that may be used in the method of producing the carbon nanotube aggregate. The substrate is, for example, a material having smoothness and high-temperature heat resistance enough to resist the production of the carbon nanotubes. Examples of such material include quartz glass, silicon (such as a silicon wafer), and a metal plate made of, for example, aluminum.

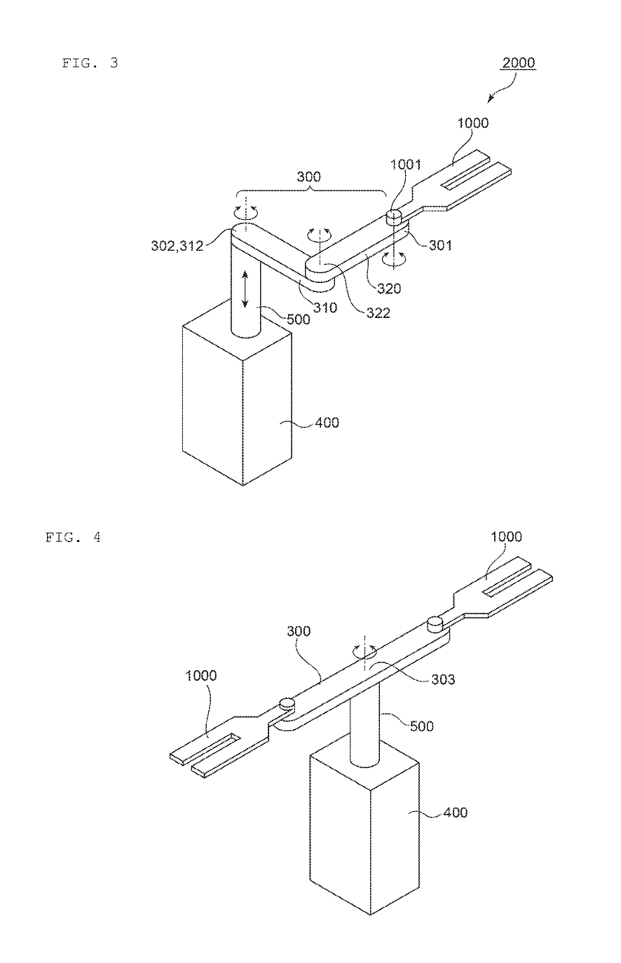

Any appropriate apparatus may be adopted as an apparatus for producing the carbon nanotube aggregate. The apparatus is, for example, a thermal CVD apparatus of a hot wall type formed by surrounding a cylindrical reaction vessel with a resistance heating electric tubular furnace as illustrated in FIG. 2. In this case, for example, a heat-resistant quartz tube is preferably used as the reaction vessel.

Any appropriate catalyst may be used as the catalyst (material for the catalyst layer) that may be used in the production of the carbon nanotube aggregate. Examples of the catalyst include metal catalysts, such as iron, cobalt, nickel, gold, platinum, silver, and copper.

In the production of the carbon nanotube aggregate, an alumina/hydrophilic film may be formed between the substrate and the catalyst layer as required.

Any appropriate method may be adopted as a method of producing the alumina/hydrophilic film. For example, the film may be obtained by producing a SiO₂ film on the substrate, depositing Al from the vapor, and increasing the temperature of Al to 450° C. after the deposition to oxidize Al. According to such production method, Al₂O₃ interacts with the hydrophilic SiO₂ film, and hence an Al₂O₃ surface different from that obtained by directly depositing Al₂O₃ from the vapor in particle diameter is formed. When Al is deposited from the vapor, and then its temperature is increased to 450° C. so that Al may be oxidized without the production of any hydrophilic film on the substrate, it may be difficult to form the Al₂O₃ surface having a different particle diameter. In addition, when the hydrophilic film is produced on the substrate and Al₂O₃ is directly deposited from the vapor, it may also be difficult to form the Al₂O₃ surface having a different particle diameter.

The thickness of the catalyst layer that may be used in the production of the carbon nanotube aggregate is preferably from 0.01 nm to 20 nm, more preferably from 0.1 nm to 10 nm in order to form fine particles. When the thickness of the catalyst layer that may be used in the production of the carbon nanotube aggregate is adjusted to fall within the above-mentioned range, the carbon nanotubes to be formed can have both excellent mechanical properties and high specific surface area, and moreover, the carbon nanotubes can provide a carbon nanotube aggregate exhibiting an excellent pressure-sensitive adhesive property. Therefore, the transport member including the carbon nanotube aggregate as described above can serve as a transport member that includes a mounting member capable of expressing a stronger gripping force and more unlikely to cause a contaminant to adhere and remain on a side of the object to be transported.

Any appropriate method may be adopted as a method of forming the catalyst layer. Examples of the method include a method involving depositing a metal catalyst from the vapor, for example, with an electron beam (EB) or by sputtering and a method involving applying a suspension of metal catalyst fine particles onto the substrate.

Any appropriate carbon source may be used as the carbon source that may be used in the production of the carbon nanotube aggregate. Examples thereof include: hydrocarbons, such as methane, ethylene, acetylene, and benzene; and alcohols, such as methanol and ethanol.

Any appropriate temperature may be adopted as a production temperature in the production of the carbon nanotube aggregate. For example, the temperature is preferably from 400° C. to 1,000° C., more preferably from 500° C. to 900° C., still more preferably from 600° C. to 800° C. in order that catalyst particles allowing sufficient expression of the effect of the present invention may be formed.

B. Transport Apparatus

A transport apparatus of the present invention includes the transport member. The transport apparatus of the present invention including the transport member may be suitably used in, for example, a manufacturing process for a semiconductor device or a manufacturing process for an optical member. More specifically, in the manufacturing process for a semiconductor device, the transport apparatus of the present invention may be used for transporting a material, a production intermediate, a product, or the like (specifically, a semiconductor material, a wafer, a chip, a film, or the like) from one step to another or in a predetermined step. Alternatively, in the manufacturing process for an optical member, the transport apparatus of the present invention may be used for transporting a glass substrate or the like from one step to another or in a predetermined step.

As described above, the transport member included in the transport apparatus of the present invention is excellent in heat resistance, and hence can maintain its retaining force for an object to be processed even under a high temperature environment. Therefore, the transport apparatus may be suitably used even in a step under a high temperature environment (e.g., at 400° C. or more, preferably from 500° C. to 1,000° C., more preferably from 500° C. to 700° C.), such as a wafer processing step (a so-called front-end step) in the manufacturing process for a semiconductor device.

As described above, the transport member included in the transport apparatus of the present invention includes the mounting member including the fibrous columnar structure, and hence the transport apparatus of the present invention exhibits a retaining force for the object to be processed under all types of environments. Specifically, the transport apparatus of the present invention exhibits the retaining force in the atmosphere and even in vacuum (e.g., at an atmospheric pressure of 10⁻⁵ Pa or less), and can be successfully used in such environment. In addition, the transport apparatus of the present invention can be successfully used also in an inert gas (e.g., helium, argon, or nitrogen).

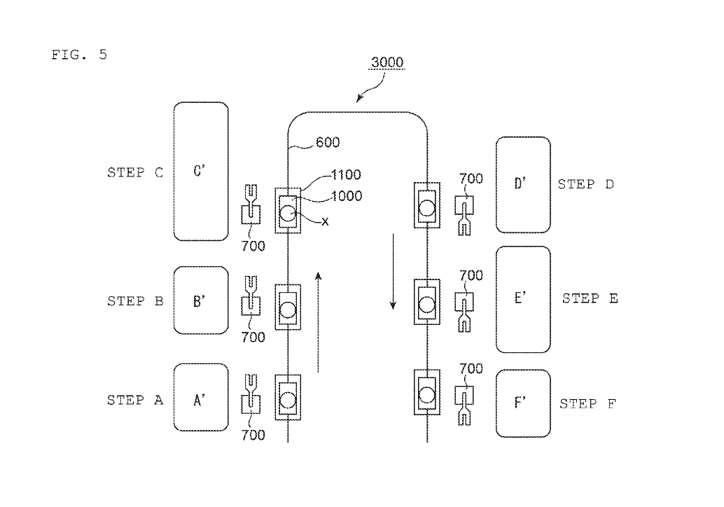

Now, specific embodiments of the present invention are described with reference to FIG. 3, FIG. 4, and FIG. 5, but the present invention is not limited to these embodiments.

In one embodiment, the transport apparatus includes an arm part and a hand part connected to one end of the arm part (FIG. 3 and FIG. 4).

FIG. 3 is a schematic view of a transport apparatus according to one embodiment of the present invention. In this embodiment, a transport apparatus 2000 includes an arm part 300 and a hand part 1000 connected to one end 301 of the arm part. The arm part 300 is arranged so as to be rotatable in a horizontal direction about another end 302 as a center of its rotation axis. More specifically, the transport apparatus 2000 includes a body part 400, the arm part 300 connected to the body part 400, and the hand part 1000 connected to a tip end of the arm part 300. The hand part 1000 is formed of the transport member, and as described above, includes the carrying member (transport table) and the mounting member arranged on the carrying member. The mounting member includes the fibrous columnar structure.

The transport apparatus 2000 of the embodiment illustrated in FIG. 3 may be used in manufacturing processes for various products, and for example, may deliver an object to be processed from one step to another step relatively close to the one step or in a step. The object to be processed to be delivered is mounted on the mounting member of the transport member constituting the hand part 1000. After that, the hand part (transport member) 1000 is moved by driving the arm part 300, to thereby transport the object to be processed on the mounting member to a subsequent step. The mounting member including the fibrous columnar structure is excellent in gripping force against a horizontal movement, and hence can strongly retain the object to be processed at the time of transport. Meanwhile, the mounting member including the fibrous columnar structure exhibits a relatively weak gripping force against a perpendicular movement, and hence an operation of removing the object to be processed from the mounting member can be simply performed without any special mechanism and any trouble.

The body part 400 serves as a base of the transport apparatus 2000.

The arm part 300 may be arranged so as to be rotatable in a horizontal direction with respect to the body part 400. In addition, the transport apparatus 2000 may include a lift part 500 for lifting up and down the arm part 300. The lift part 500 may be configured to be connected to the end portion 302 of the arm part 300 on a body part 400 side. The arm part 300 may be configured to be extendable. The rotation operation, lifting operation, and/or extension operation of the arm part 300 may be performed by being controlled by any appropriate drive mechanism (not shown). The drive mechanism may be housed in, for example, the body part 400. For example, a mechanism of a well-known structure utilizing a motor and a ball screw may be used as the drive mechanism.

As illustrated in FIG. 3, the arm part 300 may have a multi-joint structure. The arm part 300 having a multi-joint structure includes a plurality of arms (in the illustrated example, a first arm 310 and a second arm 320). The first arm 310 is arranged so as to be rotatable about an end portion 312 on a body part 400 side as a center of its rotation axis. The second arm 320 is arranged so as to be rotatable about a joint 322 as a center of its rotation axis, the joint 322 being configured to connect the first arm 310 and the second arm 320. The arm part having a multi-joint structure may include three or more arms, which does not apply only to the illustrated example. In addition, the arm constituting the arm part may be configured to be rotatable in a perpendicular direction in addition to in a horizontal direction. Further, the arm part having a multi-joint structure may be configured as a combination of an arm rotatable in a horizontal direction and another arm rotatable in a perpendicular direction. When the arm rotatable in a perpendicular direction is incorporated therein, the lift part may be omitted.

The hand part 1000 is connected to an end portion of the arm part 300 (in FIG. 3, an end portion on a side opposite to the body part 400) through intermediation of a support shaft 1001. The hand part 1000 may be arranged so as to be rotatable about the support shaft 1001 as a center of its rotation axis. The size and shape of the hand part 1000 may be appropriately selected depending on, for example, the size and shape of the object to be processed to be transported. Specific examples of the shape of the hand part 1000 include a fork form and a rectangular form. The shape of the hand part 1000 is preferably a fork form as in the illustrated example. This is because such form facilitates mounting and removal of the object to be processed.

In the embodiment in which the transport apparatus includes an arm part and a hand part connected to at least one end of the arm part, the hand part may be connected to both ends of the arm part. An example including such arm part and such hand part is illustrated in FIG. 4. In FIG. 4, the hand part 1000 is connected to both ends of the arm part 300. The arm part 300 is connected to the lift part 500 substantially at the middle of the arm part 300. In addition, the arm part 300 may be arranged so as to be rotatable in a horizontal direction substantially about the middle of the arm part 300 (preferably about a connected portion 303 to the lift part 500) as a center of its rotation axis. The hand part may be connected to both ends of the arm part having a multi-joint structure, other than in the illustrated example.

In another embodiment, a transport apparatus of the present invention may be configured to transport an object to be processed by causing the transport member to travel on a traveling track, such as a rail. FIG. 5 is a schematic view of a manufacturing process including using the transport apparatus of such embodiment. A transport apparatus 3000 includes a traveling track 600 arranged so as to connect steps (in the illustrated example, Step A to Step F), and a carriage 1100 arranged so as to travel on the traveling track 600. The transport member 1000 is arranged on the carriage 1100. As described above, the transport member 1000 includes the carrying member and the mounting member arranged on the carrying member. The mounting member includes the fibrous columnar structure. In the manufacturing process including using the transport apparatus 3000, a delivery device 700 may be arranged between the traveling track 600 and each of devices A′ to F′ to be used in the steps (e.g., a treatment device and a storage). The arrows of FIG. 5 each represent a transport direction in the transport apparatus 3000.

Also the transport apparatus 3000 illustrated in FIG. 5 may be used in manufacturing processes for various products. In the transport apparatus 3000, after the completion of a predetermined step, an object X to be processed is mounted on the transport member 1000 arranged on the carriage 1100, and transported to the next step. In the next step, the object X to be processed on the transport member 1000 is transported to a treatment device of this step and subjected to this step. The delivery of the object to be processed between each of the devices A′ to F′ to be used in the steps and the carriage 1100 is performed with the delivery device 700. Any appropriate device may be used as the delivery device 700 as long as the object X to be processed can be delivered. The transport apparatus 2000 illustrated in FIG. 3 may be used as the delivery device.

Any appropriate shape may be adopted as the shape of the traveling track 600 in a planar view.

The carriage 1100 may be driven by any appropriate drive mechanism (not shown). The sizes and shapes of the carriage 1100 and the transport member 1000 arranged on the carriage 1100 may be appropriately selected depending on, for example, the size and shape of the object to be processed to be transported. The transport apparatus 3000 may include a plurality of the carriages 1100.

The traveling speed of the carriage 1100 is preferably from 100 mm/s to 10,000 mm/s, more preferably from 500 mm/s to 5,000 mm/s, still more preferably from 1,000 mm/s to 2,000 mm/s. The mounting member including the fibrous columnar structure can strongly retain the object to be processed, and hence the traveling speed (i.e., transport speed) of the carriage 1100 can be increased in the transport apparatus of the present invention.

While an embodiment in which the traveling track 600 is configured to connect three or more steps is illustrated in FIG. 5, the transport apparatus may have a configuration in which the carriage including the transport member may reciprocate between two steps.

C. Transport Method

A transport method of the present invention includes transporting an object to be transported by retaining the object to be transported by the transport member. In one embodiment, the transport method of the present invention may be used in a manufacturing process for a semiconductor device or an optical member. More specifically, in the manufacturing process for a semiconductor device, the transport method of the present invention may be used for transporting a material, a production intermediate, a product, or the like (specifically, a semiconductor material, a wafer, a chip, a film, or the like) from one step to another or in a predetermined step. According to the transport method of the present invention, the object to be transported can be successfully retained and transported even under high temperature. In addition, the object to be transported can be successfully transported in the atmosphere, vacuum (e.g., at an atmospheric pressure of 10⁻⁵ Pa or less), an inert gas (e.g., helium, argon, or nitrogen), or the like. Specific examples of the transport method of the present invention include the methods described in the section B.

D. Method of Manufacturing Semiconductor Device

A method of manufacturing a semiconductor device of the present invention includes using the transport apparatus described in the section B. As described above, the transport apparatus includes the transport member described in the section A.

As an object to be processed to be transported by the transport apparatus in the method of manufacturing a semiconductor device, there are given, for example, a semiconductor wafer and a semiconductor chip.

In one embodiment, the method of manufacturing a semiconductor device includes a plurality of steps, and includes transporting an object to be processed to be subjected to the plurality of steps constituting the method through use of the transport apparatus. More specifically, the method of manufacturing a semiconductor device includes steps well known as manufacturing steps for a semiconductor device (e.g., a front-end step including a wafer cleaning step, a film formation step, a photolithography step, an etching step, an ion implantation step, and an inspection step; a back-end step including a wafer mounting step, a die bonding step, a wire bonding step, a packaging step, and an inspection step; and a temporal storage step for a treated object), and the object to be processed after the completion of each step is transported to the next step by the transport apparatus.

In the present invention, the transport apparatus including the transport member having a high frictional force against the object to be processed is used, and hence a semiconductor device can be manufactured while successfully retaining the object to be processed. According to the manufacturing method of the present invention, a transport speed can be increased, and hence manufacturing efficiency can be improved. In addition, the transport member is excellent in heat resistance, and hence in the manufacturing method of the present invention, a retaining force for the object to be processed is less liable to be reduced even in a step at high temperature (e.g., a front-end step), with the result that the manufacturing efficiency can be improved.

E. Method of Manufacturing Optical Member

A method of manufacturing an optical member of the present invention includes using the transport apparatus described in the section B. As described above, the transport apparatus includes the transport member described in the section A.

An object to be processed to be transported by the transport apparatus in the method of manufacturing an optical member is not particularly limited, and any of various appropriate materials may be transported. In one embodiment, a liquid crystal cell is manufactured by the manufacturing method of the present invention. As an object to be processed to be transported by the transport apparatus in the manufacture of a liquid crystal cell, there are given, for example, a glass substrate, an array substrate, and a color filter substrate.

In one embodiment, the method of manufacturing an optical member includes a plurality of steps, and includes transporting an object to be processed to be subjected to the plurality of steps constituting the method through use of the transport apparatus. When a liquid crystal cell is manufactured by the manufacturing method of the present invention, a method of manufacturing the liquid crystal cell includes steps well known as manufacturing steps for the liquid crystal cell (e.g., a substrate formation step including a glass substrate cleaning step, a step of forming various thin films, an electrode pattern formation step, and a color filter formation step; a cell assembling step; a module step; and a temporal storage step for a treated object), and the object to be processed after the completion of each step is transported to the next step by the transport apparatus.

### EXAMPLES

Now, the present invention is described by way of Examples. However, the present invention is not limited thereto. Various evaluations and measurements were performed by the following methods.

<Measurement of Length L of Fibrous Columnar Object>

The length L of a fibrous columnar object was measured with a scanning electron microscope (SEM).

<Evaluation of Wall Numbers and Wall Number Distribution of Carbon Nanotubes in Carbon Nanotube Aggregate>

The wall numbers and wall number distribution of carbon nanotubes in a carbon nanotube aggregate were measured with a scanning electron microscope (SEM) and/or a transmission electron microscope (TEM). At least 10 or more, preferably 20 or more carbon nanotubes in an obtained carbon nanotube aggregate were observed with the SEM and/or the TEM to investigate the wall number of each carbon nanotube, and the wall number distribution was created.

<Measurement of Coefficient of Static Friction Against Glass Surface>

Measurement was performed in accordance with JIS K7125.

A carbon nanotube columnar structure (80 mm×200 mm) on a silicon wafer was pressed against a polypropylene base material that had been heated to 200° C. (30 μm thick) to transfer the carbon nanotube columnar structure from the silicon wafer onto the polypropylene base material. Thus, a “carbon nanotube structure/polypropylene film” test piece having a tape shape was prepared. The carbon nanotube side of the test piece having a tape shape was placed on a slide glass (manufactured by Matsunami Glass Ind., Ltd.), a sliding piece (bottom surface: felt, 63 mm×63 mm) was placed thereon, and a weight (weight having such a weight that the total mass of the sliding piece became 200 g) was placed on the sliding piece. Under this state, the test piece was pulled at a test speed of 100 mm/min, and its coefficient of static friction was calculated from the maximum load at the time when the test piece started to move.

<Evaluation of Surface Contamination>

A carbon nanotube columnar structure was pressed against and attached onto a silicon wafer (manufactured by Silicon Technology Corporation). After that, the carbon nanotube columnar structure was peeled from the silicon wafer (manufactured by Silicon Technology Corporation) by 180° peeling. The attached surface side of the silicon wafer was subjected to morphological observation with a SEM to confirm the presence or absence of foreign matter adhering to the surface.

### Example 1

An Al thin film (thickness: 10 nm) was formed on a silicon wafer (manufactured by Silicon Technology Co., Ltd.) serving as a substrate with a sputtering apparatus (RFS-200 manufactured by ULVAC, Inc.). An Fe thin film (thickness: 1 nm) was further deposited from the vapor onto the Al thin film with the sputtering apparatus (RFS-200 manufactured by ULVAC, Inc.).

After that, the substrate was placed in a quartz tube of 30 mmφ, and a helium/hydrogen (90/50 sccm) mixed gas having its moisture content kept at 600 ppm was flowed into the quartz tube for 30 minutes to replace the inside of the tube. After that, the temperature in the tube was increased with an electric tubular furnace to 765° C. and stabilized at 765° C. While the temperature was kept at 765° C., the inside of the tube was filled with a helium/hydrogen/ethylene (85/50/5 sccm, moisture content: 600 ppm) mixed gas, and the resultant was left to stand for 5 minutes to grow carbon nanotubes on the substrate. Thus, a carbon nanotube aggregate (1) in which the carbon nanotubes were aligned in their lengthwise directions was obtained.

The length of each of the carbon nanotubes included in the carbon nanotube aggregate (1) was 100 μm.

In the wall number distribution of the carbon nanotubes included in the carbon nanotube aggregate (1), the mode was present at 2 walls, and its relative frequency was 75%.

The carbon nanotube aggregate (1) formed on the substrate was peeled from the substrate to provide a mounting member (1).

The end surface of the resultant mounting member (1) on the side peeled from the substrate was buried in an ultra-heat-resistant carbon paste (manufactured by EM Japan), and the resultant was cured (room temperature×2 hours, 90° C.×2 hours, 260° C.×2 hours, 450° C.×3 hours) and fixed onto a transport table. Thus, a transport member (1) was obtained.

The evaluation results are shown in Table 1.

### Example 2

A carbon nanotube aggregate (2) in which carbon nanotubes were aligned in their lengthwise directions was obtained in the same manner as in Example 1 except that in Example 1, the period of time for standing was changed to 25 minutes.

The carbon nanotubes included in the carbon nanotube aggregate (2) each had a length of 500 μm.

In the wall number distribution of the carbon nanotubes included in the carbon nanotube aggregate (2), the mode was present at 2 walls, and its relative frequency was 75%.

A mounting member (2) and a transport member (2) were obtained in same manner as in Example 1.

The evaluation results are shown in Table 1.

### Example 3

A carbon nanotube aggregate (3) in which carbon nanotubes were aligned in their lengthwise directions was obtained in the same manner as in Example 1 except that in Example 1, the thickness of the Fe thin film was changed to 2 nm and the period of time for standing of the reaction was changed to 35 minutes.

The carbon nanotubes included in the carbon nanotube aggregate (3) each had a length of 700 μm.

In the wall number distribution of the carbon nanotubes included in the carbon nanotube aggregate (3), the mode was present at 3 walls, and its relative frequency was 72%.

A mounting member (3) and a transport member (3) were obtained in same manner as in Example 1.

The evaluation results are shown in Table 1.

### Example 4

An Al thin film (thickness: 10 nm) was formed on a silicon substrate (manufactured by KST, wafer with a thermally oxidized film, thickness: 1,000 μm) with a vacuum deposition apparatus (manufactured by JEOL, JEE-4X Vacuum Evaporator), and was then subjected to oxidation treatment at 450° C. for 1 hour. Thus, an Al₂O₃ film was formed on the silicon substrate. On the Al₂O₃ film, an Fe thin film (thickness: 2 nm) was further deposited with a sputtering apparatus (manufactured by ULVAC, RFS-200) to forma catalyst layer.

Next, the resultant silicon substrate with a catalyst layer was cut and placed in a quartz tube of 30 mmφ, and a helium/hydrogen (120/80 sccm) mixed gas having its moisture content kept at 350 ppm was flowed into the quartz tube for 30 minutes to replace the inside of the tube. After that, the temperature in the tube was gradually increased with an electric tubular furnace to 765° C. in 35 minutes and stabilized at 765° C. While the temperature was kept at 765° C., the inside of the tube was filled with a helium/hydrogen/ethylene (105/80/15 sccm, moisture content: 350 ppm) mixed gas, and the resultant was left to stand for 5 minutes to grow carbon nanotubes on the substrate. Thus, a carbon nanotube aggregate (4) in which the carbon nanotubes were aligned in their lengthwise directions was obtained.

The carbon nanotubes included in the carbon nanotube aggregate (4) each had a length of 100 μm.

In the wall number distribution of the carbon nanotubes included in the carbon nanotube aggregate (4), the distribution width of the wall number distribution was 17 walls (4 walls to 20 walls), the modes were present at 4 walls and 8 walls, and their relative frequencies were 20% and 20%, respectively.

A mounting member (4) and a transport member (4) were obtained in same manner as in Example 1.

The evaluation results are shown in Table 1.

### Example 5

A carbon nanotube aggregate (5) in which carbon nanotubes were aligned in their lengthwise directions was obtained in the same manner as in Example 4 except that in Example 4, the period of time for standing was changed to 15 minutes.

The carbon nanotubes included in the carbon nanotube aggregate (5) each had a length of 300 μm.

In the wall number distribution of the carbon nanotubes included in the carbon nanotube aggregate (5), the distribution width of the wall number distribution was 17 walls (4 walls to 20 walls), the modes were present at 4 walls and 8 walls, and their relative frequencies were 20% and 20%, respectively.

A mounting member (5) and a transport member (5) were obtained in same manner as in Example 4.

The evaluation results are shown in Table 1.

### Example 6

A carbon nanotube aggregate (6) in which carbon nanotubes were aligned in their lengthwise directions was obtained in the same manner as in Example 4 except that in Example 4, the period of time for standing was changed to 25 minutes.

The carbon nanotubes included in the carbon nanotube aggregate (6) each had a length of 500 μm.

In the wall number distribution of the carbon nanotubes included in the carbon nanotube aggregate (6), the distribution width of the wall number distribution was 17 walls (4 walls to 20 walls), the modes were present at 4 walls and 8 walls, and their relative frequencies were 20% and 20%, respectively.

A mounting member (6) and a transport member (6) were obtained in same manner as in Example 4.

The evaluation results are shown in Table 1.

### Comparative Example 1

Polydimethylsiloxane (PDMS) (trade name: “Sylgard 184”, manufactured by Dow Corning) was used as a mounting member (C1).

The resultant mounting member (C1) was formed so as to have a thickness of 500 μm and cured to provide a transport member (C1).

The evaluation results are shown in Table 1.

TABLE 1

| | | | Coefficient | |
|---|---|---|---|---|
| | | | of static | Surface |
| | Type | Length (μm) | friction | contamination |
| Example 1 | DW-75 | 100 | 2.45 | Absent |
| Example 2 | DW-75 | 500 | 3.48 | Absent |
| Example 3 | TW-72 | 700 | 3.72 | Absent |
| Example 4 | Broad | 100 | 2.90 | Absent |
| Example 5 | Broad | 300 | 3.55 | Absent |
| Example 6 | Broad | 500 | 3.81 | Absent |
| Comparative | Silicon | 500 | 0.03 | Present |
| Example 1 | rubber | | | |

As is apparent from Table 1, the transport members to be included in the transport apparatus of the present invention each have a strong gripping force and prevent contamination of an object to be transported.

### Example 7

The transport member obtained in Example 1 was used to prepare the transport apparatus illustrated in FIG. 3. The transport apparatus was placed in an environment at 600° C. for transporting an object to be processed to a film formation step in manufacturing a semiconductor device. The object to be processed was transported by being mounted on the transport member of the transport apparatus. As a result, the object to be processed was efficiently transported without shifting in position on the transport member.

In addition, also the transport members obtained in Examples 2 to 6 were each subjected to the same transport test. Each of the transport members was able to successfully retain an object to be processed in the same manner as above.

### REFERENCE SIGNS LIST

1000 transport member
2000, 3000 transport apparatus
100 carrying member
200 binder
300 arm part
400 body part
500 lift part
600 traveling track
10 fibrous columnar structure
10a surface of fibrous columnar structure
2 fibrous columnar object

1. A transport apparatus, comprising a transport member, wherein:
the transport member comprises a carrying member and a mounting member;
the mounting member comprises a fibrous columnar structure;
the fibrous columnar structure comprises a fibrous columnar structure comprising a plurality of fibrous columnar objects;
the plurality of fibrous columnar objects are each aligned in a direction substantially perpendicular to the carrying member; and
a surface of the fibrous columnar structure on a side opposite to the carrying member has a coefficient of static friction against a glass surface of 2.0 or more.

2. The transport apparatus according to claim 1, wherein:
the transport apparatus comprises an arm part and a hand part connected to one end of the arm part;
the arm part is arranged so as to be rotatable in a horizontal direction about another end of the arm part as a center of a rotation axis; and
the hand part comprises the transport member.

3. The transport apparatus according to claim 2, wherein the arm part has a multi-joint structure.

4. The transport apparatus according to claim 1, wherein:
the transport apparatus comprises an arm part and a hand part connected to both ends of the arm part;
the arm part is arranged so as to be rotatable in a horizontal direction substantially about a middle of the arm part as a center of a rotation axis; and
the hand part comprises the transport member.

5. The transport apparatus according to claim 1, wherein the transport member is configured to travel on a traveling track.

6. The transport apparatus according to claim 5, wherein:
the transport apparatus comprises the traveling track and a carriage arranged so as to travel on the traveling track; and
the transport member is arranged on the carriage.

7. A transport method, comprising transporting an object to be transported by retaining the object to be transported by the transport member, wherein:
the transport member comprises a carrying member and a mounting member;
the mounting member comprises a fibrous columnar structure;
the fibrous columnar structure comprises a fibrous columnar structure comprising a plurality of fibrous columnar objects;
the plurality of fibrous columnar objects are each aligned in a direction substantially perpendicular to the carrying member; and
a surface of the fibrous columnar structure on a side opposite to the carrying member has a coefficient of static friction against a glass surface of 2.0 or more.

8. A transport method, comprising transporting an object to be transported by retaining the object to be transported by a transport member, wherein the transport method comprises using the transport apparatus of claim 2.

9. A method of manufacturing a semiconductor device, comprising using the transport apparatus of claim 1.

10. A method of manufacturing a semiconductor device which uses the transport apparatus of claim 1 to transport
an object that is to be processed through a plurality of steps.

11. A method of manufacturing an optical member, comprising using the transport apparatus of claim 1.

12. A method of manufacturing an optical member which uses the transport apparatus of claim 1 to transport
an object that is to be processed through a plurality of steps of [symbol]
